(19) United States
(12) Patent Application Publication
(10) Pub. No.: US 2022/0280969 A1
(43) Pub. Date: Sep. 8, 2022

(54) SUBSTRATE TREATMENT APPARATUS AND SUBSTRATE TREATMENT METHOD

(71) Applicant: Kioxia Corporation, Tokyo (JP)

(72) Inventors: Yurika KANNO, Yokkaichi Mie (JP); Hisashi OKUCHI, Yokkaichi Mie (JP); Yohei YAMAMOTO, Yokkaichi Mie (JP)

(73) Assignee: Kioxia Corporation, Tokyo (JP)

(21) Appl. No.: 17/404,898

(22) Filed: Aug. 17, 2021

(30) Foreign Application Priority Data
Mar. 8, 2021 (JP) 2021-036542

(51) Int. Cl. B05C 9/10; B05C 11/10

(52) U.S. Cl. CPC B05C 9/10; B05C 11/1013; B05C 11/1036; B05C 11/1039; B05C 11/1047

(57) ABSTRACT

In one embodiment, a substrate treatment apparatus includes a mixer configured to mix a first liquid including a metal element and a second liquid being basicity to generate a third liquid including the metal element and being basicity. The apparatus further includes a supplier configured to supply the third liquid to a substrate. The apparatus further includes a first flow path configured to convey the third liquid from the mixer to the supplier not through a filter that removes particles from the third liquid.

### CROSS REFERENCE TO RELATED APPLICATION

This application is based upon and claims the benefit of priority from the prior Japanese Patent Application No. 2021-036542, filed on Mar. 8, 2021, the entire contents of which are incorporated herein by reference.

### FIELD

Embodiments described herein relate to a substrate treatment apparatus and a substrate treatment method.

### BACKGROUND

When a metal element is supplied to a substrate by supplying a chemical solution including the metal element to the substrate, it is preferable to employ a method that allows the metal element to be suitably supplied to the substrate.

### BRIEF DESCRIPTION OF THE DRAWINGS

FIG. 1 is a schematic diagram illustrating a configuration of a substrate treatment apparatus of a first embodiment;

FIG. 2 is a schematic diagram illustrating a configuration of a substrate treatment apparatus of a second embodiment;

FIG. 3 is a flowchart for describing an operation of the substrate treatment apparatus of the second embodiment; and

FIG. 4 is a graph for describing an operation of the substrate treatment apparatus of the second embodiment.

### DETAILED DESCRIPTION

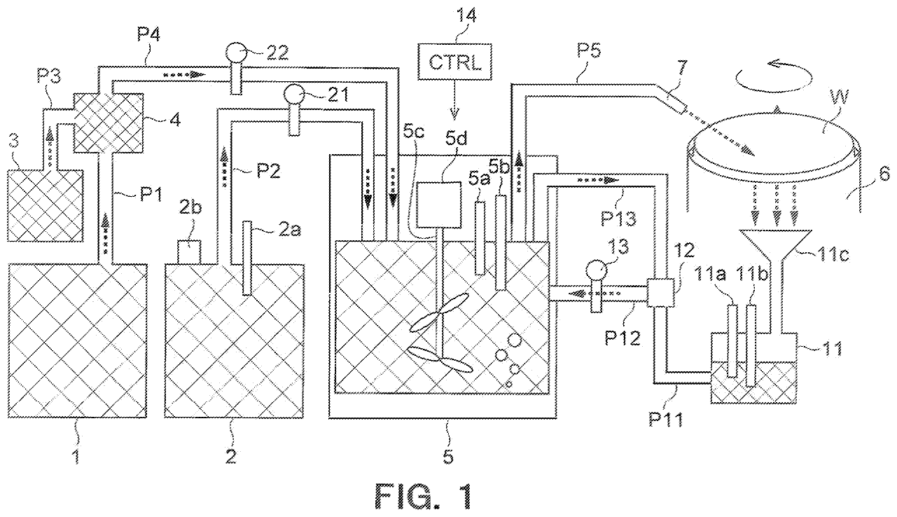

Embodiments will now be explained with reference to the accompanying drawings. In FIGS. 1 to 4, the same components are denoted by the same reference signs to omit redundant explanation.

In one embodiment, a substrate treatment apparatus includes a mixer configured to mix a first liquid including a metal element and a second liquid being basicity to generate a third liquid including the metal element and being basicity. The apparatus further includes a supplier configured to supply the third liquid to a substrate. The apparatus further includes a first flow path configured to convey the third liquid from the mixer to the supplier not through a filter that removes particles from the third liquid.

### First Embodiment

FIG. 1 is a schematic diagram illustrating a configuration of a substrate treatment apparatus of a first embodiment. The substrate treatment apparatus in FIG. 1 is used to treat a substrate W with a chemical solution.

The substrate treatment apparatus in FIG. 1 includes an aqueous metal solution tank 1, an aqueous ammonia tank 2, a pure water tank 3, a dilution tank 4, a mixing tank 5, a table 6, a nozzle 7, a collecting tank 11, a cut filter 12, a flow meter 13, a controller 14, a valve 21, and a valve 22. The aqueous metal solution tank 1, the pure water tank 3, and the dilution tank 4 are examples of a first liquid supplier; and the aqueous ammonia tank 2 is an example of a second liquid supplier. The mixing tank 5 is an example of a mixer; and the nozzle 7 is an example of a supplier. The collecting tank 11 is an example of a collector; and the cut filter 12 is an example of a filter.

In addition, the aqueous ammonia tank 2 includes a pH meter 2a and a detector 2b. The mixing tank 5 includes a pH meter 5a, an absorptiometer 5b, an agitator 5c, and a motor 5d. The pH meter 5a and the absorptiometer 5b are examples of a measuring instrument. The collecting tank 11 includes a pH meter 11a, an absorptiometer 11b, and a waste liquid collecting mechanism 11c.

The substrate treatment apparatus in FIG. 1 further includes flow paths P1, P2, P3, P4, P5, P11, P12, and P13. The flow paths P1, P2, P3, P4, P5, P11, P12, and P13 are formed, for example, by piping. The flow path P5 is an example of a first flow path; the flow paths P11 and P12 are examples of a second flow path; and the flow path P13 is an example of a third flow path.

Hereinafter, details of the substrate treatment apparatus of the present embodiment will be described with reference to FIG. 1

The aqueous metal solution tank 1 is used to store an aqueous metal solution including a metal element. Examples of this metal element include a transition metal element and a rare-earth metal element. For example, the aqueous metal solution of the present embodiment includes, as the metal element, nickel (Ni), cobalt (Co), copper (Cu), iron (Fe), tungsten(W), aluminum (Al), palladium (Pd), rhodium (Rh), platinum (Pt), gold (Au), silver (Ag), lead (Pb), manganese (Mn), ruthenium (Ru), chromium (Cr), titanium (Ti), niobium (Nb), iridium (Ir), or tantalum (Ta). In addition, the aqueous metal solution of the present embodiment includes such a metal element in the form of ions. The aqueous metal solution is, for example, an aqueous nitric acid solution, aqueous hydrochloric acid solution, aqueous acetic acid solution, aqueous formic acid solution, aqueous sulfuric acid solution, aqueous oxalic acid solution, aqueous sulfamic acid solution, or aqueous carbonic acid solution which includes metal ions. For example, when the aqueous metal solution is an aqueous nickel acetate (Ni(COOH)₂) solution, the metal element is an Ni element and the ions are Ni²⁺ ions. The aqueous metal solution in the aqueous metal solution tank 1 is conveyed to the dilution tank 4 through the flow path P1.

The aqueous ammonia tank 2 is used to store highly-concentrated aqueous ammonia. The aqueous ammonia is an aqueous solution of ammonia (NH₃) and exhibits basicity. The pH of this aqueous ammonia is, for example, 10 or higher; preferably, 10 or higher and 12 or lower; more preferably, 11 or higher and 12 or lower. In addition, the concentration of ammonia in this aqueous ammonia is, for example, 28 wt % or higher. The aqueous ammonia in the aqueous ammonia tank 2 is conveyed to the mixing tank 5 through the flow path P2. The aqueous ammonia in the aqueous ammonia tank 2 is an example of a second liquid.

The pH meter 2a measures the pH of the aqueous ammonia in the aqueous ammonia tank 2 and outputs its measurement result to the controller 14. The detector 2b detects an ammonia gas. When detecting an ammonia gas, it outputs an alarm. Since the substrate treatment apparatus of the present embodiment uses aqueous ammonia, an ammonia gas may be generated in the substrate treatment apparatus. The detector 2b is provided to notify persons of the occurrence of an ammonia gas. An alarm may be output in any mode; for example, it may be output in the form of an alarm sound, an alarm screen, an alarm mail, an alarm lamp, or an alarm indicator. The detector 2b of the present embodiment is provided outside a housing of the substrate treatment apparatus so as to detect the leakage of an ammonia gas outside the housing of the substrate treatment apparatus. In addition, the detector 2b may output a signal indicating that an ammonia gas has been detected, to the controller 14. In this case, the controller 14 may output an alarm.

The pure water tank 3 is used to store pure water. This pure water is, for example, ultra-pure water that is pure water having high purity. The pure water in the pure water tank 3 is conveyed to the dilution tank 4 through the flow path P3.

The dilution tank 4 dilutes the aqueous metal solution from the aqueous metal solution tank 1 with the pure water from the pure water tank 3, to generate an aqueous metal solution having a lower concentration of the metal element than the aqueous metal solution from the aqueous metal solution tank 1. The dilution tank 4 generates, for example, an aqueous metal solution with a Ni²⁺ ion concentration of 1.0×10⁻⁴ mol/L or higher and 1.0×10⁻¹ mol/L or lower. In this case, the concentration of Ni²⁺ ions in the aqueous metal solution is controlled by the controller 14, for example. The aqueous metal solution generated in the dilution tank 4 is conveyed to the mixing tank 5 through the flow path P4. The aqueous metal solution generated in the dilution tank 4 is an example of a first liquid.

The mixing tank 5 mixes the aqueous metal solution from the dilution tank 4 and the aqueous ammonia from the aqueous ammonia tank 2, to generate a chemical solution that includes a metal element and exhibits basicity. In the present embodiment, the aqueous metal solution and aqueous ammonia react with each other, thereby generating an ammine complex including a metal element. Therefore, a chemical solution of the present embodiment is an aqueous solution including the ammine complex. For example, when the aqueous metal solution is an aqueous nickel acetate solution, this chemical solution is a solution including an Ni element in the ammine complex (aqueous hexa-ammine-nickel complex solution). The chemical solution generated in the mixing tank 5 is conveyed to the nozzle 7 through the flow path P5. The chemical solution generated in the mixing tank 5 is an example of a third liquid. The mixing tank 5 of the present embodiment is a closed-system mixing tank.

The pH meter 5a measures the pH of the chemical solution in the mixing tank 5 and outputs its measurement result to the controller 14. This measurement result of pH is used by the controller 14 to control the pH of the chemical solution in the mixing tank 5. The controller 14 controls the pH of the chemical solution in the mixing tank 5 so that, for example, the pH of the chemical solution in the mixing tank 5 is 10 or higher, preferably 10 or higher and 12 or lower, and more preferably 11 or higher and 12 or lower. For example, when a pH measurement value of the pH meter 5a is lower than 11, the controller 14 increases the pH of the chemical solution in the mixing tank 5 to a value of 11 or higher. More specifically, the controller 14 performs control so that the pH measurement value of the pH meter 5a is 11 or higher. More details of the pH control by the controller 14 will be described later.

The absorptiometer 5b measures the absorbance of the chemical solution in the mixing tank 5 and outputs its measurement result to the controller 14. This measurement result of absorbance is used by the controller 14 to control the metal concentration in the chemical solution in the mixing tank 5. Examples of the metal concentration include the concentration of Ni atoms in the chemical solution. The absorbance of the chemical solution can be used to evaluate the metal concentration in the chemical solution. The controller 14 controls the metal concentration in the chemical solution in the mixing tank 5 so that, for example, the metal concentration in the chemical solution in the mixing tank 5 is 1.0×10⁻⁴ mol or higher and 1.0×10⁻¹ mol/L or lower. For example, when a metal concentration corresponding to an absorbance measurement value of the absorptiometer 5b is lower than 1.0×10⁻⁴ mol/L, the controller 14 increases the metal concentration in the chemical solution in the mixing tank 5 to a value of 1.0×10⁻⁴ mol/L or higher. More specifically, the controller 14 performs control so that the metal concentration corresponding to an absorbance measurement value of the absorptiometer 5b is 1.0×10⁻⁴ mol/L or higher. More details of the metal concentration control by the controller 14 will be described later. The agitator 5c agitates the chemical solution in the mixing tank 5 by rotating in the mixing tank 5. This makes it possible to achieve uniform pH and metal concentration in the chemical solution in the mixing tank 5. The motor 5d is attached to the agitator 5c and can rotate the agitator 5c. The rotating operation of the motor 5d is controlled, for example, by the controller 14.

The table 6 is used to support and rotate the substrate W. The rotating operation of the table 6 is controlled, for example, by the controller 14.

The nozzle 7 is used to supply the chemical solution from the mixing tank 5 to the substrate W. The nozzle 7 of the present embodiment discharges the chemical solution onto an upper surface of the substrate W on the table 6 that is rotating. This allows the substrate W to be treated with the chemical solution. In the present embodiment, the chemical solution is supplied to the substrate W, thereby allowing a metal element in the chemical solution to be supplied to the substrate W. For example, metal atoms in the chemical solution can be adhered to a surface of the substrate W and can be introduced to an inside of the substrate W. The substrate W of the present embodiment includes an amorphous silicon layer and Ni atoms in the chemical solution are attached to a surface of the amorphous silicon layer. In this case, the concentration of Ni atoms on the surface of the amorphous silicon layer can be controlled by adjusting the concentration of Ni atoms in the chemical solution, for example. The discharge operation of the nozzle 7 is controlled, for example, by the controller 14.

Although the substrate W is supplied with the chemical solution by a spin-coating method using the nozzle 7 in the present embodiment, the chemical solution may be supplied by other methods. For example, the substrate W may be supplied with the chemical solution by spraying of the chemical solution or immersion in the chemical solution. In addition, although the substrate W is treated in a sheet-fed manner in the present embodiment, it may be treated in a batch manner.

The collecting tank 11 collects the chemical solution that has been supplied to the substrate W. This allows the chemical solution that has been supplied to the substrate W to be reused. The chemical solution collected by the collecting tank 11 is conveyed to the cut filter 12 through a flow path P11.

The pH meter 11a measures the pH of the chemical solution in the collecting tank 11 and outputs its measurement result to the controller 14. The absorptiometer 11b measures the absorbance of the chemical solution in the collecting tank 11 and outputs its measurement result to the controller 14. The waste liquid collecting mechanism 11c is a mechanism that collects the chemical solution (waste liquid) that has been supplied to the substrate W. The chemical solution of the present embodiment is discharged from the nozzle 7 to the substrate W on the table 6 and is collected in the collecting tank 11 through the waste liquid collecting mechanism 11c.

The cut filter 12 is provided between the flow path P11 and the flow path P12 and collects dust from the chemical solution that flows from the collecting tank 11 to the mixing tank 5. More specifically, the cut filter 12 of the present embodiment removes particles from the chemical solution. This makes it possible to supply the chemical solution, from which particles have been removed, to the mixing tank 5. This particles are, for example, of a metal oxide that is generated from the chemical solution. The chemical solution that has passed through the cut filter 12 is conveyed to the mixing tank 5 through the flow path P12 and is reused in the mixing tank 5.

The flow meter 13 is provided in the flow path P12 and measures the flow rate of the chemical solution that flows through the flow path P12 in a downstream of the cut filter 12. If clogging of the cut filter 12 occurs due to particles, the flow rate measured by the flow meter 13 decreases. Therefore, the flow rate measured by the flow meter 13 can be used to detect clogging of the cut filter 12. The flow meter 13 outputs a measurement result of the flow rate to the controller 14. The chemical solution that has passed through the flow meter 13 is conveyed to the mixing tank 5 through the flow path P12.

The controller 14 controls various operations of the substrate treatment apparatus of the present embodiment. The controller 14 of the present embodiment supplies the chemical solution from the mixing tank 5 to the cut filter 12 through the flow path 13, based on the measurement result of the flow rate which has been received from the flow meter 13. For example, when the above flow rate is higher than a threshold, the controller 14 closes a valve (unillustrated) provided in the flow path P13 to stop supply of the chemical solution from the mixing tank 5 to the cut filter 12. On the other hand, when the above flow rate is lower than the threshold, the controller 14 opens the valve to supply the chemical solution from the mixing tank 5 to the cut filter 12. This makes it possible to change a particle attached to the cut filter 12 to an ammine complex. This ammine complex is collected together with the chemical solution, in the mixing tank 5. In this way, the particles can be removed from the cut filter 12, thereby allowing clogging of the cut filter 12 to be released. The chemical solution supplied from the mixing tank 5 to the cut filter 12 is collected into the mixing tank 5 through the flow path P12. Supply of the chemical solution from the mixing tank 5 to the cut filter 12 may be performed, for example, within a period for which the substrate treatment apparatus is not treating the substrate W such as during maintenance of the substrate treatment apparatus.

The controller 14 further can control the pH of the aqueous ammonia in the aqueous ammonia tank 2, based on the measurement result of the pH which has been received from the pH meter 2a. This allows the above-described pH of the aqueous ammonia to be obtained. The controller 14 further can control the pH and metal concentration in the chemical solution in the mixing tank 5, based on the measurement results of the pH and absorbance which have been received from the pH meter 5a and the absorptiometer 5b, respectively. This makes it possible to obtain the above-described pH and metal concentration in the chemical solution. The controller 14 yet further can control the pH and metal concentration in the chemical solution in the collecting tank 11, based on the measurement results of the pH and absorbance which have been received from the pH meter 11a and the absorptiometer 11b, respectively. The pH meters 2a, 5a, and 11a may output, to the controller 14, measurement results of the temperatures of the aqueous ammonia and chemical solution, in addition to the measurement results of the pH of the aqueous ammonia and chemical solution.

The controller 14 of the present embodiment can control the pH and metal concentration in the chemical solution in the mixing tank 5, by controlling the valve 21 provided in the flow path P2 and the valve 22 provided in the flow path P4. For example, when the pH of the chemical solution in the mixing tank 5 is low, the opening of the valve 21 is increased to increase the flow rate of aqueous ammonia passing through the valve 21. This makes it possible to increase the pH of the chemical solution in the mixing tank 5. When the metal concentration in the chemical solution in the mixing tank 5 is low, the opening of the valve 22 is increased to increase the flow rate of the chemical solution passing through the valve 22. This makes it possible to increase the metal concentration in the chemical solution in the mixing tank 5.

In addition, the controller 14 of the present embodiment may control the pH of the chemical solution in the mixing tank 5 by ammonia gas bubbling or with a buffer. Examples of the buffer include ammonium nitrate, ammonium sulfate, ammonium chloride, and ammonium hydroxide. This makes it possible to control the pH of the chemical solution in the mixing tank 5 by means other than the valves 21 and 22. In this case, a mechanism for ammonia gas bubbling or a mechanism for a buffer is provided in the mixing tank 5. The controller 14 controls this mechanism so as to allow the pH of the chemical solution in the mixing tank 5 to be controlled by the ammonia gas bubbling or with the buffer.

As described above, the substrate treatment apparatus of the present embodiment supplies the chemical solution from the mixing tank 5 to the substrate W and thereby, treats the substrate W with the chemical solution. This makes it possible to attach Ni atoms in the chemical solution to the amorphous silicon layer in the substrate W. The substrate W is then annealed outside the substrate treatment apparatus, for example. As a result, the amorphous silicon layer is crystalized. The chemical solution of the present embodiment may be used to treat a layer other than the amorphous silicon layer of the substrate W.

Next, more details of the substrate treatment apparatus of the present embodiment will be described still with reference to FIG. 1.

The controller 14 of the present embodiment controls the pH of the chemical solution in the mixing tank 5 so that the pH of the chemical solution in the mixing tank 5 is 11 or higher. Such control has advantages described below.

For example, assume a case where the chemical solution in the mixing tank 5 includes metal ions (for example, Ni²⁺ ions) and has a pH lower than 7. In this case, the chemical solution in the mixing tank 5 is acidic. Supply of this chemical solution to the amorphous silicon layer (a-Si layer) allows metal atoms to be attached to a surface of the a-Si layer. However, in this case, the concentration of metal atoms on the surface of the a-Si layer may not reach a concentration required for crystallization of the a-Si layer.

In addition, assume that a chemical solution is generated by adding a basic material to an aqueous solution including metal ions so as to make the pH of the chemical solution in the mixing tank 5 equal to or higher than 7 and lower than 10. In this case, the chemical solution in the mixing tank 5 is basic (alkaline). Depending on the kind of this chemical solution, a hydroxide of the above metal can be generated by control of the pH of the chemical solution. When this chemical solution is supplied to the a-Si layer, the metal hydroxide is absorbed on the a-Si layer. This makes it possible to make the concentration of metal atoms on the surface of the a-Si layer reach a concentration required for crystallization of the a-Si layer. In this case, the amount of generated metal hydroxide is determined by the content of metal ions in the above aqueous solution and the amount of added basic material. Therefore, by appropriately setting the content and the amount of addition, the amount of generated metal hydroxide can be increased, so that the concentration of metal atoms on the surface of the a-Si layer can be increased. However, when this chemical solution is supplied to the a-Si layer, absorption of the metal hydroxide on the a-Si layer and deposition of the metal hydroxide in the chemical solution concurrently occur and this makes the metal concentration in the chemical solution on the a-Si layer lower than a desired metal concentration. As a result, the concentration of metal atoms on the surface of the a-Si layer may not reach the desired concentration. In addition, when a fixed number of aggregates of the metal hydroxide that have precipitated in the chemical solution are adhered to the surface of the a-Si layer, a portion including a high concentration of metal may locally occur on the surface of the a-Si layer. Such a portion may adversely affect the crystallization of the a-Si layer.

The deposition of the metal hydroxide in this chemical solution also occurs in the flow path P5 between the mixing tank 5 and the nozzle 7. To avoid this, it can be considered to arrange a filter for removing particles from the chemical solution, in the flow path P5, as with the cut filter 12. This makes it possible to remove the metal hydroxide as particles from the chemical solution in the flow path P5, allowing the adhesion of aggregates as described above to be prevented. However, when the filter is arranged in the flow path P5, a problem of a decrease in the metal concentration in the chemical solution occurs.

To avoid this, the substrate treatment apparatus of the present embodiment controls the pH of the chemical solution in the mixing tank 5 by the controller 14 so that the pH of the chemical solution in the mixing tank 5 is 11 or higher. When the pH of the chemical solution is 11 or higher, the deposition of the metal hydroxide in the chemical solution is prevented. This makes it possible to prevent the adhesion of the aggregates described above without arranging, in the flow path P5, a filter for removing particles from the chemical solution. Therefore, the substrate treatment apparatus of the present embodiment does not include such a filter in the flow path P5 and conveys the chemical solution from the mixing tank 5 to the nozzle 7 not through such a filter. This makes it possible to prevent a problem of causing the metal concentration in the chemical solution to decrease through a filter.

As described above, the present embodiment makes it possible to sufficiently increase the concentration of metal atoms on the surface of the a-Si layer by using a basic chemical solution. In addition, the present embodiment makes it possible to prevent the adhesion of the aggregates to the surface of the a-Si layer without using a filter, by controlling the pH of the chemical solution in the mixing tank 5. Furthermore, the present embodiment makes it possible to prevent a problem of causing the metal concentration in the chemical solution to decrease, by conveying the chemical solution by using the flow path P5 without a filter. Yet furthermore, the present embodiment makes it possible to control the concentration of metal atoms on the surface of the a-Si layer by controlling the metal concentration in the chemical solution by the controller 14. As described above, the present embodiment makes it possible to suitably supply a metal element to the substrate W.

### Second Embodiment

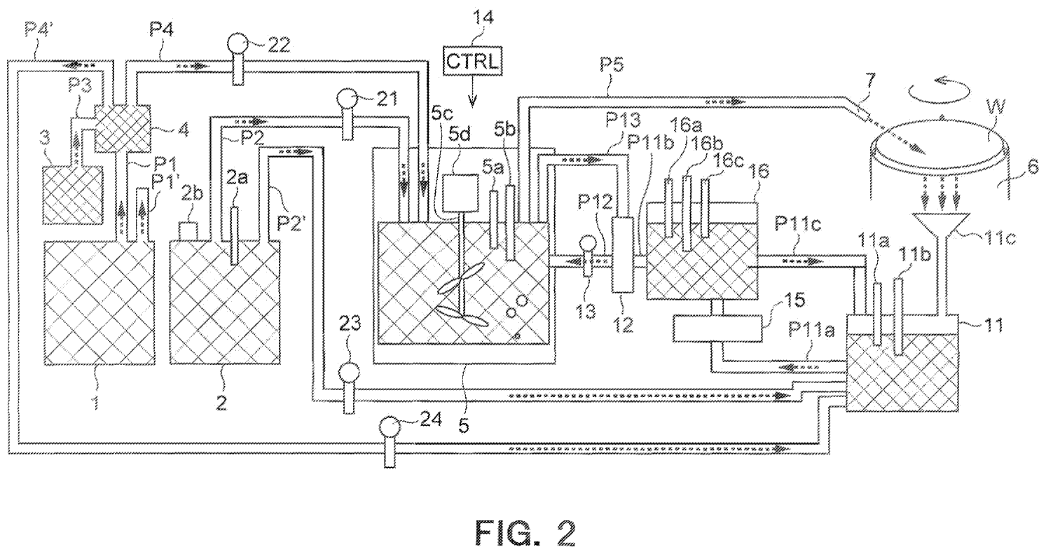

FIG. 2 is a schematic diagram illustrating a configuration of a substrate treatment apparatus of a second embodiment.

The substrate treatment apparatus in FIG. 2 includes, in addition to the components of the substrate treatment apparatus in FIG. 1, a pre-cut filter 15, a pre-mixing tank 16, a valve 23, a valve 24, and flow paths P1′, P2′, and P4′. The pre-mixing tank 16 includes a pH meter 16a, an absorptiometer 16b, and a particle counter 16c. The pre-mixing tank 16 is an example of a pre-mixer.

The substrate treatment apparatus in FIG. 2 further includes flow paths P11a, P11b, and P11c, as flow paths P11. The pre-cut filter 15 is provided in the flow path P11a. The pre-mixing tank 16 is provided between the flow path P11a, the flow path P11b, and the flow path P11c. The flow paths P1′, P2′, and P4′, and the flow paths P11a, P11b, and P11c are formed, for example, by piping.

Hereinafter, details of the substrate treatment apparatus of the present embodiment will be described with reference to FIG. 2.

In the first embodiment, the chemical solution discharged from the collecting tank 11 is filtered by the cut filter 12, supplied to the mixing tank 5, and mixed in the mixing tank 5. On the other hand, in the present embodiment, the chemical solution discharged from the collecting tank 11 is filtered by the pre-cut filter 15 in advance, supplied to the pre-mixing tank 16, and mixed in the mixing tank 16 in advance. The chemical solution discharged from the pre-collecting tank 16 is filtered by the cut filter 12, supplied to the mixing tank 5, and mixed in the mixing tank 5.

The pre-cut filter 15 collects dusts from the chemical solution flowing from the collecting tank 11 to the pre-mixing tank 5 through the flow path 11a. More specifically, the pre-cut filter 15 of the present embodiment removes particles from the chemical solution, as with the cut filter 12. This makes it possible to supply the chemical solution, from which particles have been removed, to the pre-mixing tank 16. This particles are, for example, of a metal hydroxide that is generated from the chemical solution. The chemical solution that has passed through the pre-cut filter 15 is conveyed to the pre-mixing tank 16 through the flow path P11a.

The pre-mixing tank 16 performs mixture of the chemical solution that flows therein from the pre-cut filter 15, and discharges a mixed chemical solution to the flow path P11b or the flow path P11c. The chemical solution discharged to the flow path P11b is conveyed to the cut filter 12. The chemical solution discharged to the flow path P11c is returned to the collecting tank 11.

The pH meter 16a measures the pH of the chemical solution in the pre-mixing tank 16 and outputs its measurement result to the controller 14. The absorptiometer 16b measures the absorbance of the chemical solution in the pre-mixing tank 16 and outputs its measurement result to the controller 14. The particle counter 16c counts the number of particles detected from the chemical solution in the pre-mixing tank 16 and outputs its count result to the controller 14.

The flow paths P1′, P2′, and P4′ extend to the collecting tank 11 from the aqueous metal solution tank 1, the aqueous ammonia tank 2, and the dilution tank 4, respectively. Note that an illustration of a part of the flow path P1′ is omitted. The flow path P1′ conveys the aqueous metal solution in the aqueous metal solution tank 1 to the collecting tank 11. The flow path P2′ conveys the aqueous ammonia in the aqueous ammonia tank 2 to the collecting tank 11. The flow path P4′ conveys the aqueous metal solution generated in the dilution tank 4 to the collecting tank 11. The valve 23 is provided in the flow path P2′. The valve 24 is provided in the flow path P4′.

Next, more details of the substrate treatment apparatus of the present embodiment will be described still with reference to FIG. 2.

In the present embodiment, the controller 14 controls the pH of the chemical solution in the mixing tank 5 so that the pH of the chemical solution in the mixing tank 5 is 11 or higher and 12 or lower. Therefore, the nozzle 7 discharges the chemical solution having a pH of 11 or higher and 12 or lower to the substrate W. The collecting tank 11 collects the chemical solution having a pH that has decreased in comparison with the pH at the nozzle 7. This is because the pH of the chemical solution decreases due to treatment of the substrate W.

When the chemical solution in the collecting tank 11 is supplied as is to the mixing tank 5, the pH of the chemical solution in the mixing tank 5 decreases. For example, in a case where the pH of the chemical solution in the mixing tank 5 is 11 and the pH of the chemical solution in the collecting tank 11 is 10, when the chemical solution in the collecting tank 11 is supplied as is to the mixing tank 5, the pH of the chemical solution in the mixing tank 5 becomes lower than 11. In this case, the controller 14 is required to return the pH of the chemical solution in the mixing tank 5 to 11 again.

To reduce such an inefficiency, the controller 14 of the present embodiment controls pH of the chemical solution in the collecting tank 11 so as to make the pH of the chemical solution in the collecting tank 11 closer to the PH of the chemical solution in the mixing tank 5. The controller 14 of the present embodiment further may control the metal concentration in the chemical solution in the collecting tank 11 so as to make the metal concentration in the chemical solution in the collecting tank 11 closer to the metal concentration in the chemical solution in the mixing tank 5. The controller 14 of the present embodiment can control the pH and metal concentration in the chemical solution in the mixing tank 11, by controlling the valve 23 provided in the flow path P2′ and the valve 24 provided in the flow path P4′. For example, when the pH of the chemical solution in the collecting tank 11 is low, the opening of the valve 23 is increased to increase the flow rate of aqueous ammonia passing through the valve 23. This makes it possible to increase the pH of the chemical solution in the mixing tank 11. When the metal concentration in the chemical solution in the collecting tank 11 is low, the opening of the valve 24 is increased to increase the flow rate of the chemical solution passing through the valve 24. This makes it possible to increase the pH of the chemical solution in the collecting tank 11. The controller 14 can perform such pH control and metal concentration control by using the pH measured by the pH meter 11a and the absorbance measured by the absorptiometer 11b.

Such control can be implemented also in the pre-mixing tank 16. The controller 14 may control the pH of the chemical solution in the pre-mixing tank 16 so as to make the pH of the chemical solution in the pre-mixing tank 16 closer to the pH of the chemical solution in the mixing tank 5. The controller 14 further may control the metal concentration in the chemical solution in the pre-collecting tank 16 so as to make the metal concentration in the chemical solution in the pre-collecting tank 16 closer to the metal concentration in the chemical solution in the mixing tank 5. The controller 14 can perform such pH control and metal concentration control by using the pH measured by the pH meter 16a and the absorbance measured by the absorptiometer 16b.

For example, in a case where the pH of the chemical solution in the mixing tank 5 is 11 and the pH of the chemical solution immediately after being collected by the collecting tank 11 is 10, the controller 14 may control the pH of the chemical solution in the collecting tank 11 so that the pH of the chemical solution in the collecting tank is approximately 11. In this case, the controller 14 roughly adjusts the pH of the chemical solution in the collecting tank 11 to 11 and finely adjusts the pH of the chemical solution in the pre-collecting tank 16 to 11. As a result, the chemical solution having a pH of 11 is returned to the mixing tank 5 and therefore, the pH of the chemical solution in the mixing tank 5 can be prevented from decreasing due to the chemical solution from the pre-collecting tank 16.

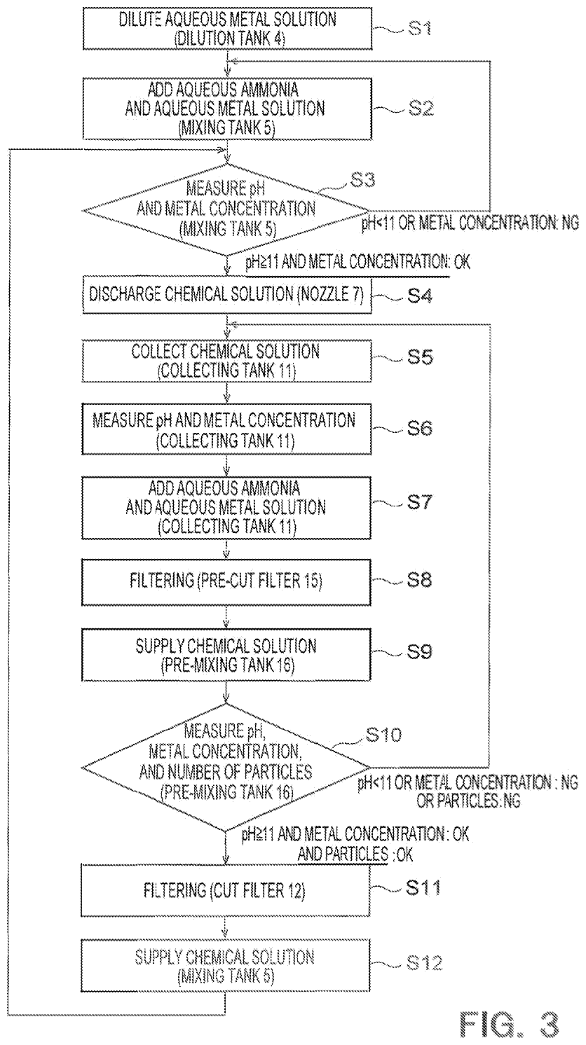

FIG. 3 is a flowchart for describing an operation of the substrate treatment apparatus of the second embodiment.

First, the aqueous metal solution supplied from the aqueous metal solution tank 1 is diluted in the dilution tank 4 (step S1). Next, the aqueous ammonia supplied from the aqueous ammonia tank 2 and the aqueous metal solution supplied from the dilution tank 4 are added to an existing chemical solution in the mixing tank 5 and these liquids are mixed together by the agitator 5c (step S2).

Next, the pH and absorbance (metal concentration) of the chemical solution in the mixing tank 5 are measured by using the pH meter 5a and the absorptiometer 5b (step S3). If the controller 14 determines that the pH measured by the pH meter 5a is lower than 11 or the metal concentration measured by the absorptiometer 5b is not a desired concentration, processing returns to step S2. If the controller 14 determines that the pH measured by the pH meter 5a is 11 or higher and the metal concentration measured by the absorptiometer 5b is a desired concentration, the processing advances to step S4.

At step S4, the nozzle 7 discharges the chemical solution from the mixing tank 5 to the substrate W. Next, this chemical solution is collected in the collecting tank 11 (step S5). Next, the pH and absorbance (metal concentration) of the chemical solution in the collecting tank 11 are measured by using the pH meter 11a and the absorptiometer 11b (step S6). Next, the aqueous ammonia supplied from the aqueous ammonia tank 2 and the aqueous metal solution supplied from the dilution tank 4 are added to an existing chemical solution in the collecting tank 11 (step S7). In this point, the controller 14 determines the amount of addition of aqueous ammonia and aqueous metal solution to the solution in the collecting tank 11, based on the pH measured by the pH meter 11a and the metal concentration measured by the absorptiometer 11b.

Next, the chemical solution discharged from the collecting tank 11 is filtered by the pre-cut filter 15 (step S8). Next, the chemical solution that has passed through the pre-cut filter 15 is supplied to the pre-mixing tank 16 (step S9).

Next, the pH, absorbance (metal concentration), and number of particles of the chemical solution in the pre-mixing tank 16 are measured by using the pH meter 16a, the absorptiometer 16b, and the particle counter 16c (step S10). If the controller 14 determines that the pH measured by the pH meter 16a is lower than 11, the metal concentration measured by the absorptiometer 16b is not a desired concentration, or the number of particles measured by the particle counter 16c is a threshold or more, the processing returns to step S5. If the controller 14 determines that the pH measured by the pH meter 16a is 11 or higher, the metal concentration measured by the absorptiometer 16b is a desired concentration, and the number of particles measured by the particle counter 16c is less than the threshold, the processing advances to step S11.

At step S11, the chemical solution discharged from the pre-collecting tank 16 is filtered by the cut filter 12. Next, the chemical solution that has passed through the cut filter 12 is supplied to the mixing tank 5 and is mixed again in the mixing tank 5 (step S12). In this way, the chemical solution discharged to the substrate W is reused in the mixing tank 5. The process of steps S1 to S12 is repeated until the treatment of the substrate W is complete.

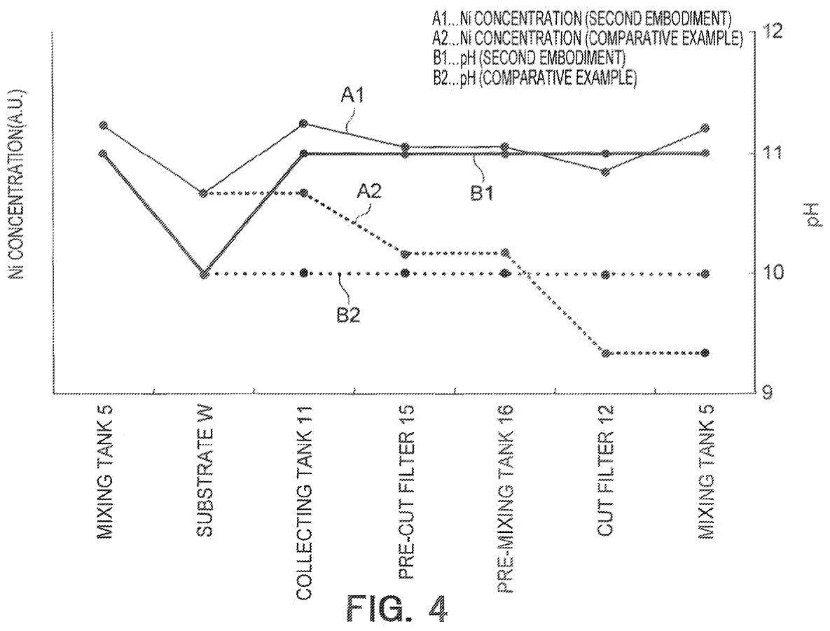

FIG. 4 is a graph for describing an operation of the substrate treatment apparatus of the second embodiment.

Lines A1 and B1 illustrated in FIG. 4 respectively represent examples of changes in the Ni concentration and pH of the chemical solution that occur when the chemical solution of the present embodiment is discharged from the mixing tank 5 and returns to the mixing tank 5 again via the substrate W, the collecting tank 11, the pre-cut filter 15, the pre-mixing tank 16, and the cut filter 12.

Lines A2 and B2 illustrated in FIG. 4 respectively represent examples of changes in the Ni concentration and pH of the chemical solution that occur when a chemical solution of a comparative example of the present embodiment is discharged from the mixing tank 5 and returns to the mixing tank 5 again. In the above comparative example, the chemical solution discharged from the collecting tank 11 returns to the mixing tank as is.

In the above comparative example, the pH of the chemical solution in the mixing tank 5 is 11 but the pH of the chemical solution on the substrate W decreases to 10 (B2). This is due to, for example, volatilization of ammonia from the chemical solution. In addition, in the above comparative example, the chemical solution having a pH of 10 returns to the mixing tank 5.

Likewise, in the present embodiment, the pH of the chemical solution in the mixing tank 5 is 11 but the pH of the chemical solution on the substrate W decreases to 10 (B1). This is due to the same reason as that in the above comparative example. However, in the present embodiment, the pH of the chemical solution increases to approximately 11 in the collecting tank 11 and the chemical solution having a pH of 11 returns to the mixing tank 5. This is because the pH control described above is performed in the collecting tank 11 and the pre-mixing tank 16.

In addition, in the above comparative example, the Ni concentration in the chemical solution decreases due to discharge of the chemical solution to the substrate W and it significantly decreases also during a return of the chemical solution from the collecting tank 11 to the mixing tank 5 (A2). This is due to, for example, the adhesion of metal atoms to the substrate W and the deposition of metal atoms out of the chemical solution during a return of the chemical solution from the collecting tank 11 to the mixing tank 5.

Likewise, in the present embodiment, the Ni concentration in the chemical solution decreases due to discharge of the chemical solution to the substrate W (A1). This is due to the same reason as in the above comparative example. However, the Ni concentration in the chemical solution changes only a little during a return of the chemical solution from the collecting tank 11 to the mixing tank 5. This is because the metal concentration control described above is performed in the collecting tank 11 and the pre-mixing tank 16. As for the line Al in FIG. 4, the metal concentration in the chemical solution increases due to the addition of the aqueous metal solution to the chemical solution.

As described above, the substrate treatment apparatus of the present embodiment includes the pre-cut filter 15 and the pre-mixing tank 16 in addition to the components of the substrate treatment apparatus of the first embodiment. Therefore, the present embodiment makes it possible to suitably control the pH and metal concentration in the chemical solution that is returned from the collecting tank 11 to the mixing tank 5.

While certain embodiments have been described, these embodiments have been presented by way of example only, and are not intended to limit the scope of the inventions. Indeed, the novel apparatuses and methods described herein may be embodied in a variety of other forms; furthermore, various omissions, substitutions and changes in the form of the apparatuses and methods described herein may be made without departing from the spirit of the inventions. The accompanying claims and their equivalents are intended to cover such forms or modifications as would fall within the scope and spirit of the inventions.

1. A substrate treatment apparatus comprising:
a mixer configured to mix a first liquid including a metal element and a second liquid being basicity to generate a third liquid including the metal element and being basicity;
a supplier configured to supply the third liquid to a substrate; and
a first flow path configured to convey the third liquid from the mixer to the supplier not through a filter that removes particles from the third liquid.

2. The apparatus of claim 1, further comprising a controller configured to control at least either a pH or a metal concentration of the third liquid in the mixer.

3. The apparatus of claim 2, further comprising a measuring instrument configured to measure a value regarding the third liquid in the mixer,
wherein the controller controls at least either the pH or the metal concentration of the third liquid, based on the value measured by the measuring instrument.

4. The apparatus of claim 3, wherein
the measuring instrument includes a pH meter configured to measure the pH of the third liquid, and an absorptiometer configured to measure absorbance of the third liquid; and
the controller controls the pH of the third liquid based on the pH measured by the pH meter, and controls the metal concentration of the third liquid based on the absorbance measured by the absorptiometer.

5. The apparatus of claim 2, wherein the controller controls the pH of the third liquid so that the pH of the third liquid is 11 or higher.

6. The apparatus of claim 2, wherein the controller controls the pH of the third liquid in the mixer by bubbling or with a buffer.

7. The apparatus of claim 6, wherein the buffer includes ammonium nitrate, ammonium sulfate, ammonium chloride or ammonium hydroxide.

8. The apparatus of claim 1, wherein the mixer includes an agitator configured to agitate the third liquid.

9. The apparatus of claim 1, wherein the metal element is a transition metal element or a rare-earth metal element.

10. The apparatus of claim 1, wherein the metal element is nickel (Ni), cobalt (Co), copper (Cu), iron (Fe), tungsten (W), aluminum (Al), palladium (Pd), rhodium (Rh), platinum (Pt), gold (Au), silver (Ag), lead (Pb), manganese (Mn), ruthenium (Ru), chromium (Cr), titanium (Ti), niobium (Nb), iridium (Ir) or tantalum (Ta).

11. The apparatus of claim 1, wherein the first liquid is an aqueous solution including ions of the metal element, the second liquid is aqueous ammonia, and the third liquid is an aqueous solution including an ammine complex having the metal element.

12. The apparatus of claim 11, wherein a concentration of the ions in the first liquid is 1.0×10⁻⁴ mol/L or higher and 1.0×10⁻¹ mol/L or lower.

13. The apparatus of claim 11, wherein a pH of the second liquid is 10 or higher and a concentration of ammonia in the second liquid is 28 wt % or higher.

14. The apparatus of claim 1, wherein the supplier includes a nozzle configured to discharge the third liquid to the substrate on a stage.

15. The apparatus of claim 1, wherein the apparatus comprising:
a first liquid supplier configured to supply the first liquid to the mixer; and
a second liquid supplier configured to supply the second liquid to the mixer,
wherein the first liquid supplier generates the first liquid by diluting a liquid including a higher concentration of the metal element than the first liquid, and supplies the generated first liquid to the mixer.

16. The apparatus of claim 1, further comprising:
a collector configured to collect the third liquid having been supplied to the substrate; and
a second flow path configured to convey the third liquid from the collector to the mixer.

17. The apparatus of claim 16, wherein the apparatus comprising:
a filter provided in the second flow path and configured to remove the particles from the third liquid;
a flow meter provided downstream of the filter in the second flow path and configured to measure a flow rate of the third liquid; and
a third flow path configured to supply the third liquid from the mixer to the filter,
wherein the controller supplies the third liquid from the mixer to the filter via the third flow path, based on the flow rate measured by the flow meter.

18. The apparatus of claim 16, further comprising:
a pre-mixer provided in the second flow path and configured to mix the third liquid from the collector to supply the third liquid to the mixer; and
a particle counter configured to count a number of particles in the third liquid in the pre-mixer.

19. A substrate treatment apparatus comprising:
a mixer configured to mix a first liquid including a metal element and a second liquid being basicity to generate a third liquid including the metal element and being basicity;
a supplier configured to supply the third liquid to a substrate;
a measuring instrument configured to measure a value regarding the third liquid; and
a controller configured to control at least either a pH or a metal concentration of the third liquid, based on the value measured by the measuring instrument.

20. A substrate treatment method comprising:
mixing a first liquid including a metal element and a second liquid being basicity by a mixer to generate a third liquid including the metal element and being basicity;
conveying the third liquid from the mixer to a supplier not through a filter that removes particles from the third liquid; and
supplying the third liquid to a substrate by the supplier.
